(19) United States
(12) Patent Application Publication
(10) Pub. No.: US 2026/0141655 A1
(43) Pub. Date: May 21, 2026

(54) METHOD AND SYSTEM FOR SIMULATING THREE-DIMENSIONAL APPARELS ON THREE-DIMENSIONAL HUMAN BODY

(71) Applicants: Nachiket KULKARNI, Pune, Maharashtra (IN); Manoj WAD, Pune, Maharashtra (IN)

(72) Inventors: Nachiket KULKARNI, Pune (IN); Vikash VIKASH, Bhiwani (IN); Jagriti MAURYA, Jaunpur Uttar (IN)

(73) Assignees: Nachiket KULKARNI, Pune, Maharashtra (IN); Manoj WAD, Pune, Maharashtra (IN)

(21) Appl. No.: 19/122,495

(22) PCT Filed: Oct. 21, 2023
(86) PCT No.: PCT/IN2023/050976

§ 371 Date: Apr. 18, 2025

(30) Foreign Application Priority Data
Oct. 21, 2022 (IN) 202221045009

(51) Int. Cl. G06T 19/20; G06F 30/27

(52) U.S. Cl. CPC G06T 19/20; G06F 30/27

(57) ABSTRACT

Disclosed is a system and method for simulating apparels on human body 100. The system 100 receives body parameters and apparel data from a plurality of users 105. The system 100 includes a dataset collection module 242 for storing apparel data and body parameters. The system 100 also includes a NN trainer module 254 for training the neura tech module 244. The system 100 also includes an visualization module 246 for draping apparel data and body parameters and creating an simulation. The system 100 also includes a lookmap module 248 for mapping colours and textures on the simulated model. The system 100 also includes a Fitmap module 250 for predicting fit and loose areas of apparels on a particular body.

### FIELD OF THE INVENTION

The present invention relates to simulation system and more particularly relates to system and method for virtually draping three-dimensional clothing apparels on three dimensional human body in any pose or a sequence of poses.

### BACKGROUND OF THE INVENTION

Virtual try-on is becoming more and more popular in the modern era and the development of online shopping. The users can see themselves in selected beloved clothes on the screen of their smartphone. Online retailers also know that enabling their customers to try-on products virtually is beneficial to their business.

Presently, shopping malls or retailers do not allow or allow only selected apparels for consumers to try on. Probably, the consumers are not allowed to wear the apparels due to strict rules, damage to the apparel, maintain hygiene and the like. Currently, there are different apparel brands located in different regions of the world.

Each apparel brands have different fitting, style, comfort that makes it difficult for the consumers to predict one size for different brands. Although sizes of apparels are defined the feel and fitting of them differ from one apparel to another. Hence, it makes the consumers difficult to predict apparel fitting of different brands without trying on. There have been attempts in the prior art to overcome such problems some of them are discussed below.

Australian Patent AU20132661841 to Jonathan Coon et. al. relates to systems and methods for adjusting a virtual try-on. The AU2013266184C1 discloses a computer-implemented method for generating a virtual try-on to obtain a first model and a second model. The first model includes a first set of attachment points. The second model includes a first set of connection points. The first model and the second model are combined such that combining the first and second models includes matching the first set of attachment points with the first set of connection points. An image is rendered based on at least a portion of the combined first and second models.

U.S. Pat. No. 11,315,324B2 to Hisao Yoshioka et al. is a virtual try-on system for clothing. An acquisition unit of a first terminal acquires a try-on subject image. A first calculator calculates composite position information indicating a composite position of a clothing image in the try-on subject image. A first transmission unit transmits, to a server device, user information including the try-on subject image and the composite position information. A second reception unit of the server device receives the user information from the first terminal.

WO2018027549A1 to Shenzhen Saiyi science and tech development company is a system and method for trying on clothes virtually. It describes a three-dimensional body model that is built for trying on clothes on-site in real-time virtually. The virtual fitting system has a user body characteristic parameter acquisition system, a human body three-dimensional model two-dimensional code generation system and a merchant terminal system.

KR20190023486A to Lookseedo co ltd is a method and apparatus for providing 3D fitting. The method and apparatus provides a 3D fitting method that allow consumers to virtually fit clothing to the body shape of each consumer. The method and apparatus includes a body information verifying unit; an avatar generation unit, an apparel data generating unit, and a virtual fitting unit for performing a fitting simulation for combining the clothing data with the body avatar data.

Upon receipt of second information including a signal of request for execution of virtual try-on from a portable second terminal, a second transmission unit transmits third information including the user information and the clothing image to the second terminal. A third transmission unit of the second terminal transmits the second information to the server device. A third reception unit receives the third information from the server device. A third storage unit stores the received third information.

There is a need of a method and system for real-time simulation of apparels on the user-specific body parameters. There is also a need for draping minute texture details of the apparel on the simulated body. There is a further need of predicting fit and loose regions of a particular apparel draped on a particular body. There is also a need to simulate the apparel on bodies in different poses. There is also need for temporal sequence of movements of the body and corresponding movement of the apparel.

### SUMMARY OF THE INVENTION

A system for simulating three dimensional apparels on three dimensional human body includes a plurality of electronic devices. The system includes a user interface unit communicating through the plurality of electronic devices. The system includes a processing unit processing data received from the user interface unit for generating a first digital object as per user inputs, a second digital object by fetching that from a dataset collection module in accordance with the users selection, and storing first and second digital object in the database unit.

The user interface unit includes a trial module that is configured to simulate plurality of apparels draped on three-dimensional human body as per the parameters entered by the users. The processing unit includes a neura tech module that is configured to provide the second dataset after processing the first digital object and the second digital object as input. A secondary digital object on the size and shape of the body defined by body parameter in a pose defined by pose parameter. The neura tech module communicates the second dataset to a post-processing module.

The post-processing module is configured to correct the position of apparel draped vertices i.e., the second dataset. The processing unit includes a lookmap module that is configured to map colour and textures of the apparels obtained from the post-processing module. The processing unit includes a fitmap module that is configured to process the second dataset modified by the post processing module to visualise the fit of the apparel on the body as simulated by the lookmap module. The visualization module is configured for rendering the first and the second dataset in a three-dimensional representation.

The user interface unit includes a data input module for receiving body measurement parameters, cloth parameters and frame number. The dataset collection module collects plurality of apparels draped on plurality of human bodies in a given pose with their body, pose and apparel parameters attached to them. The lookmap module is configured to provide a 3D digital mesh texture or colour to the apparel data received from the post processing module.

The fitmap module predicts the fit or loose portion of the apparel. The post-processing module includes a clipping correction module that is configured to find and fix the body point to identify the position of the apparel inside or outside the rendered body. The neura tech module is configured to drape the apparel on the user defined body parameters through a NN trainer module.

A method for simulating three-dimensional apparel on three dimensional human body including steps of receiving first and second digital objects; creating a second dataset through neura tech module; removing artifacts with the help of post processing module; mapping texture details on an apparel through lookmap module; finding areas of the apparel fitting tightly or loosely through the fitmap module; and rendering the modified second dataset on user's digital 3D body through visualization module.

A method of training the neura tech module including steps of: creating training dataset; configuring body, pose, apparel parameters as inputs to NN trainer module; Initializing neural network model; Providing all inputs from the training dataset to neural network model to generate predicted output; Comparing predicted output with training dataset to calculate loss; and Adjusting weights of each layer to minimize the loss till we reach acceptable loss.

A method for creating a training data set including steps of: creating ‘l’ number of bodies with ‘x’ number of body parameters; creating ‘m’ number of apparels with ‘y’ number of apparel parameters; creating ‘n’ number of poses with ‘z’ number of pose parameters; simulating all apparels on all bodies in all poses; and storing all of l*m*n variations as ideal drape data.

### BRIEF DESCRIPTION OF THE DRAWINGS

The objectives and advantages of the present invention will become apparent from the following description read in accordance with the accompanying drawings wherein

FIG. 1 shows a system for simulating three dimensional apparels on three-dimensional human body communicating with the user in accordance with the present invention;

FIG. 2 shows a system architecture of the system for simulating three dimensional apparels on three-dimensional human body of FIG. 1;

FIG. 3 shows the architecture of the Neura Tech Module of FIG. 2 in accordance with the present invention;

FIG. 4 shows a flow chart of system for simulating three dimensional apparels on three-dimensional human body; and

FIG. 5 shows a flow chart of neural network training module on three-dimensional human body.

### DETAILED DESCRIPTION OF THE INVENTION

The invention herein is described using specific exemplary details for better understanding. However, the invention disclosed can be worked on by a person skilled in the art without the use of these specific details.

References in the specification to “one embodiment” or “an embodiment” means that particular feature, structure, characteristic, or function described in connection with the embodiment is included in at least one embodiment of the invention. The appearances of the phrase “in one embodiment” in various places in the specifications are not necessarily all referring to the same embodiment.

References in the specification to “preferred embodiment” means that a particular feature, structure, characteristic, or function described in detail thereby omitting known constructions and functions for clear description of the present invention.

The present invention is illustrated with reference to the accompanying drawings, throughout which reference numbers indicate corresponding parts in the various figures.

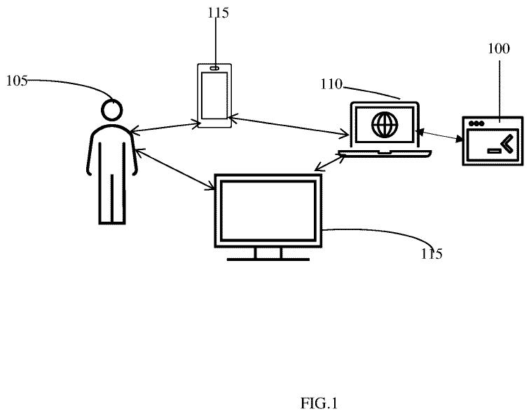

Referring to FIG. 1, a system for simulating three-dimensional apparels on three-dimensional human body 100 (hereinafter referred to as “the system”) in accordance with a preferred embodiment of the present invention is described. The system 100 communicates with the users 105 through a plurality of electronic devices 115. In context of the present invention, the users 105 are the individuals accessing the system 100. In this embodiment the plurality of electronic devices 115 are preferably Laptops, Computers, Handheld devices and the like however, the type of electronic devices varies in other embodiments of the present invention.

The users 105 accesses the system 100 preferably through Internet 110, Intranet, Wired Network, Local Area Network (LAN), Wide Area Network (WAN) or the like. The system 100 virtually simulates and drapes selected objects for example apparel, clothes, wears or the like, on human body with desired shape and size. A plurality of users 105 simultaneously access the system 100 through a plurality of electronic devices 115.

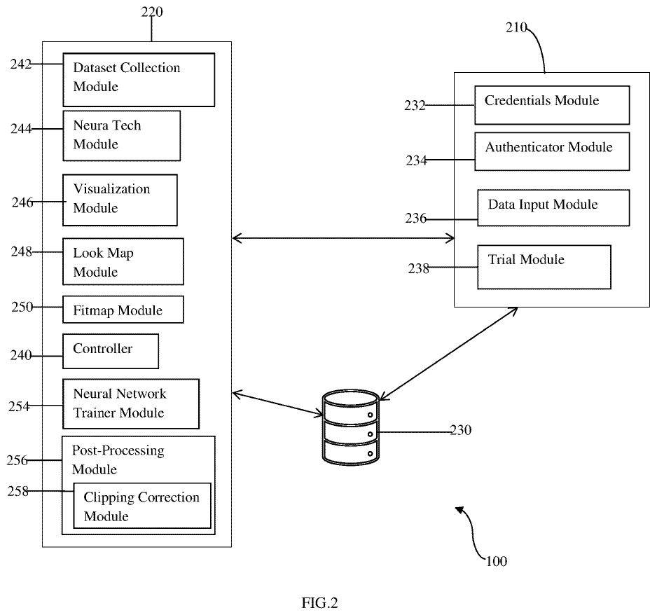

Referring to FIG. 2 the system 100 is described hereinafter. The system 100 includes a user interface unit 210, a processing unit 220 and a database unit 230. The user interface unit 210 includes a credentials module 232, an authenticator module 234, a data input module 236 and a trial module 238. The credentials module 232 is configured to register new users and authenticate the registered users 105 in the system 100. The authenticator module 234 communicates with the database 230 for registering the new users and authenticating the new and registered users 105 with the system 100. The data input module 236 receives user's body parameters from the users 105. The trial module 238 is configured to simulate the user defined three-dimensional apparel to be draped on user defined three-dimensional body.

The processing unit 220 includes a dataset collection module 242, a neura tech module 244, a visualization module 246, a lookmap module 248, a fitmap module 250 and a controller 240. The neura tech module 244 drapes the simulated three-dimensional digital apparel on the three-dimensional simulated human body as per the user defined body parameters. The visualization module 246 simulates three-dimensional view of the user body and the apparel. The lookmap module 248 maps the colour and textures of a respective apparel on a simulated three-dimensional model. The fitmap module 250 is configured to determine a fit or loose regions of an apparel.

The processing unit 220 also includes a neural network trainer module 254 hereinafter, referred to as ‘NN trainer module’ and a post-processing module 256. The NN trainer module 254 is configured to train the neura tech module 244 as per the predefined data stored in the dataset collection module 242. The user interface unit 210 stores and retrieves data from the database unit 230 through the processing unit 220.

In accordance with the present invention, one or more users 105 of the system 100 register with the system 100 by recording the user identification details. After registration the users 105 enter the Login credentials to access the system 100. The login module 232 is configured to record new users 105 with the system 100. Further, the authentication module 234 validates the received credentials against the saved credentials in the database 230 and accordingly allows the users 105 to access the system. The users 105 enter predefined body parameters, cloth parameter and frame number through the data input module 236.

In this preferred embodiment, the users 105 enters his/her body measurements data. It is to be noted that, the body measurement data includes parameters like height of the user, shoulder length, neck to hip length, hip to leg length, arm length, chest front end perimeter, stomach front end perimeter, waist front end perimeter and the like. The data input module 236 further generates a first digital object from the body measurement data provided by the user 105.

The first digital object may be generated by an image or a three-dimensional object representing the user 105 and being provided by the user to the data input module 236. In accordance with the present invention, the first digital object, has specifications that represents the user 105 body shape in two dimensional, three dimensional and in 360 degrees orientation. The first digital object is received by the neura tech module 244 and the NN trainer module 254 to generate a secondary digital object.

Further, the trial module 238 simulates plurality of apparels draped on human body as per the body parameters entered by the users 105 and the predefined apparel parameters. On the contrary, the trial module 238 also simulates plurality of apparels draped on existing human bodies of various shapes and sizes if the users 105 do not enter any predefined body and apparel data through the data input module 236.

The dataset collection module 242 collects and stores three-dimensional apparel and apparel parameters as well as three-dimensional human body and human body parameters of various shapes and sizes for various poses with pose value through physics body simulators. In accordance with the present invention, every apparel is assigned a set of numerical values for example, to simulate a t-shirt the parameters like sleeve length, length of the front and back side, shoulder length of apparel as well as the type of the material are stored in the dataset collection module 242.

Accordingly, the set of numerical values include texture of the apparel, patterns or designs on the apparel, colour of the apparel, material of the apparel or the like. Similarly, based on the different apparel type the parameters are received from the user and accordingly stored inside the dataset collection module 242. In accordance with the present invention, a first dataset is a collection of bodies created in accordance with the first digital object of the present invention. The first dataset is stored in the dataset collection module 242 along with the first digital object. The various poses are also represented in numerical format. In this embodiment, the numerical representation of the pose is referred to as pose parameters. In the present invention, the pose parameter is encoded as frame number of animation and stored in data collection module 242.

The numerical values of apparels are used to train the neura tech module 244. Each human body in the same way is defined by predefined numerical values. The dataset collection module 242 collects plurality apparels draped on plurality of human bodies in plurality of poses with their body and cloth and pose parameters attached to them.

The NN trainer module 254 receives a first digital object, a second digital object and frame numbers from the dataset collection module 242. In this present embodiment, the second digital object includes numerical values of apparel data. Accordingly, the apparel data is a set of predefined numerical values which defines the size, shape and material of the apparel and are calculated using predefined systems. In accordance with the present invention, the body parameters are a set of predefined numerical values which defines the shape and size of the body.

In accordance with the present invention, the NN trainer module 254 is configured to train the neura tech module 244. In accordance with the present invention, the NN training module 254 includes training data. The training data includes for example 35 human body shapes selected by the artists in such a way that their height and weights cover all possible permutations and combinations of body types and are stored as 3D files. Further, template data of 15 clothes are made for different sizes of a given apparel type.

Accordingly, for example, said template data for T-Shirt have different sizes and shape like XS, S, M, L, XL, and fitting type like regular fit, slim fit and relaxed fit and so on making the 15 clothes as mentioned above. Further, these template data are like unstitched pieces of fabrics as a tailor would cut before stitching them. Hence, the template data are in pieces like torso and sleeves separate and they are stitched together on bodies to create different sizes of clothes draped on different sizes of bodies.

The neura tech module 244 is trained to drape the three-dimensional digital apparel of the size, shape and material defined by the apparel data on the size and shape of the body defined by body parameter in a pose defined by frame numbers. The ‘draping of apparel data on the human body’ is hereinafter referred to as a second data set i.e., ‘draped data’. For every frame of the body, the neura tech module 244 predicts cloth vertices for the garment of required size based on data received from the database unit 230.

The visualization module 246 receives a second dataset of draped data of apparel on human body from the neura tech module 244. In accordance with the present invention, the visualization module 246 is configured to simulate the 360° view of the body as well as apparel as per a selected frame. Now, the lookmap module 248 receives apparel data from neura tech module 244. The lookmap module 248 is configured to map colour and textures of the apparels obtained from the predefined system on a 3D apparel data as received from the neura tech module 244.

In this present embodiment, the lookmap module 248 is devised with UV mapping 3D modelling process however, the 3D modelling process varies in other embodiments of the present invention. In context of the present invention, ‘U’ and ‘V’ in the UV mapping denotes the axes of the 2D texture. The UV mapping (hereinafter referred as ‘UV’) gives a 3D digital mesh texture or colour to the apparel data received from the neura tech module 244.

In accordance with the present invention, the lookmap module 248 is configured with GAN (Generative Adversarial Network) that converts the texture data from the apparel data into its equivalent UV axes. The GAN is a machine learning (ML) model in which two neural networks compete with each other to become more accurate in their predictions. The lookmap module 248 simulates fine details of the apparel draped on the respective human body and simulates coloured simulation of apparels draped on the human body.

The postprocessing module 256, the nearest vertex on the body is found with respect to each vertex on the apparel. If the nearest vertex comes out to be negative, then the apparel is actually under the skin. In such instances, we will have to adjust it so that it will come out and give it a new position based on the neighbouring vertices which are actually outside the body and body geometry. Further, the postprocessing module 256 smoothens the modified vertices in the above step to improve the appearance of the apparels.

The fitmap module 250 is configured to predict the fitting of apparel in a given area based on the physics-based cloth simulation data. After we have ascertained whether the apparel fits or not, the fitmap module 250 paints each vertex in a certain colour that shows the degree by which the apparel fits on the body for e.g., green for loose, red for tight and the intensity of colour represents how loose or tight the apparel is fitting over a body.

The post processing module 256 is configured to remove the part of the cloth which is inside the body and smoothen the cloth to eliminate noise. The post-processing module 256 includes a clipping correction module 258. In the clipping correction module 258, any vertex ‘A’ on the cloth is taken. Accordingly, in the clipping correction module 258 the position of vertex ‘A’ is identified whether it is inside or outside the body.

Further, in the clipping correction module 258 to determine the position of vertex ‘A’ a nearest body vertex ‘B’ is determined. Further, a vector is drawn from ‘A’ to ‘B’ hereinafter referred as ‘AB’. Moreover, the dot product between vector ‘AB’ and another vector which is a vertex normal at body point ‘B’ is calculated. Ultimately, a negative dot product defines, the position of the apparel is inside the body otherwise the apparel is positioned on or over the body.

In accordance with the present invention, the clipping correction module 258 is configured to find the point if the point is found out to be inside, a small value is added to this vertex in the direction of body normal vector at the nearest body point B. A value is added until the vertex is detected as outside by a dot product algorithm. The fitmap module 250 is configured to process the apparel data as simulated by the post-processing module 256. The fitmap module 250 predicts the fit of the simulated apparel on the three-dimensional human body and informs the users 105 the parts of the apparel that fit tight or loose on respective body.

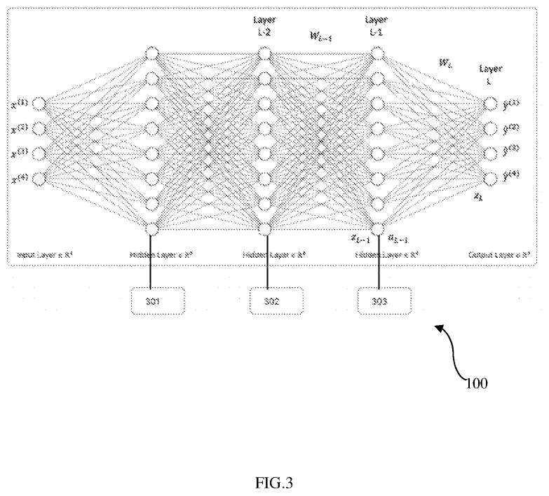

Referring to FIG. 3 system architecture of a neura tech module 244 is described hereinafter. The neural network architecture is a type of fully connected neural network. This type of network only contains fully connected layers as hidden layers apart from input and output layers. In accordance with the present invention the neural network includes of three layers a first layer 301, a second layer 302 and a third layer 303.

Each of these fully connected layers contain neurons which are connected to every neuron in previous and next layers as shown in FIG. 3. The neurons are a representation of a mathematical operation which is equal to the weighted sum of outputs from all neurons from the previous layers and the weight is that parameter that the neural network model is trying to learn.

The number of fully connected layers in our model are three and the number of neurons in each layer are selected based on experimentation and are different for each layer and are 150,15000 and 20148 respectively. The neural network trains by an algorithm known as backward propagation where the weights of each neuron are updated based on the difference in output from the model and ground truth output that is used to train the model.

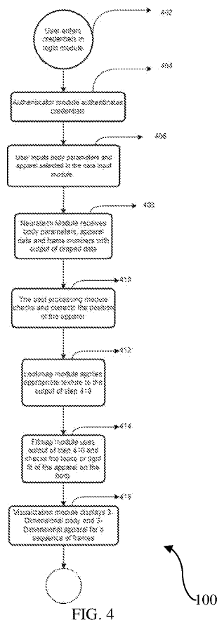

Now referring to FIGS. 1-4 an operational flow of the system for simulating apparels on human body 100 is described. In an initial step 402 operation, the users 105 accesses the system 100 using internet 110 through electronic devices 115. In this step 402, the registered users 105 logs into the system 100 through the login module 232. In a next step 404, the authentication module 234 authenticates the users 105 with the system 100. In a further step 406, the users 105 input body measurements and apparel data into the system 100 through data input module 236. In a further step 408, the neura tech module 244 receives body parameters and apparel data from previous step and drapes said apparel data over respective body parameters. In a next step 410, the post-processing module 256 is configured to correct the clipping with the help of clipping correction module 258. In a further step 412, the lookmap module 248 maps the colour and texture obtained from the apparel data over a three-dimensional apparel data as produced by the post processing 256.

In this step 412, the lookmap module 248 maps 2D image parameters on a three-dimensional apparel data and produces a coloured simulation of apparel data draped on body parameters. In a next step 414, the fitmap module 250 processes the apparel data and predicts the fit or loose areas of the apparel draped on the human body and represents it in various colours. In a last step 416, the visualization module 246 simulates a 360° view of the human body draped with provided body measurements and apparel data. The system 100 displays simulation along with suggestions through the trial module 238.

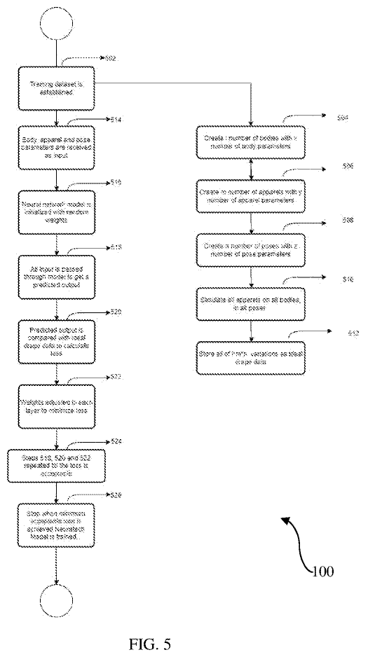

Now referring to FIG. 5 an operational flow of neural network training module is described hereinafter. In an initial step 502, a training dataset is defined by storing the simulated plurality of draped apparels on plurality of bodies in plurality of poses in data collection module 242 that is used as expected output. In a further step 504, ‘l’number of bodies with ‘x’ number of body parameters created. In a further step 506, ‘m’ number of apparels with ‘y’ number of apparel parameters are created. In a next step 508 ‘n’ number of poses with ‘z’ number of pose parameters are created. In a further step 510, all apparels on all bodies in all poses are simulated. In a next step 512, all of l*m*n variations as ideal drape data are stored.

In a next step 514, body, apparel and pose parameters are used as input numerical values. In a next step 516, the neural network model is initialised by some random weights. In a next step 518, the l*m*n inputs are passed through the model one by one in a step called forward propagation and output is calculated defined as predicted output and the process of one pass through the whole dataset is called one epoch.

In a next step 520, the output is compared with the output corresponding to those inputs received from the training dataset. The loss function is calculated by comparing these two and calculating loss. In a next step 522, based on a minimum loss, the gradients are calculated and weights in each layer are updated such that predicted value comes close to the training dataset value that is defined as backward propagation. In a next step 524, the flow steps 518, 520 and 522 are repeated by the controller until the different inputs and outputs coming from dataset collection module 242 are calculated. In a final step 526, the neural network model is trained by above-mentioned steps for many epochs until the loss is at the minimum level and is acceptable to the user 105.

The system 100 advantageously, help users to make an informed choice while online shopping for apparels, users will be aware of how the apparel fits on his\her body and how various colours and designs look on him\her. The system 100 advantageously, assists cloth vendors in lowering the amount of order returns they frequently encounter. The system 100 advantageously, buyers may view the clothes on themselves without physically visiting the store. The system 100 advantageously, save time by trying clothing on virtually at home and placing your order whenever you're ready.

The foregoing description of specific embodiments of the present invention has been presented for purposes of illustration and description. They are not intended to be exhaustive or to limit the present invention to the precise forms disclosed, and obviously many modifications and variations are possible in light of the above teaching.

The embodiments were chosen and described In order to best explain the principles of the present invention and its practical application, to thereby enable others, skilled in the art to best utilize the present invention and various embodiments with various modifications as are suited to the particular use contemplated.

It is understood that various omission and substitutions of equivalents are contemplated as circumstance may suggest or render expedient, but such are intended to cover the application or implementation without departing from the scope of the present invention.

1. A system for simulating three dimensional apparels on three dimensional human body 100 including a plurality of electronic devices 115 characterized in that said system 100 comprising:
a user interface unit 210 communicating through the plurality of electronic devices 115, a processing unit 220 processing data received from the user interface unit 210 generating a first digital object as per user inputs, a second digital object by fetching that from a dataset collection module 242 in accordance with the users 105 selection, and storing first and second digital object in the database unit 230;
the user interface unit 210 includes a trial module 238 that is configured to simulate plurality of apparels draped on 3D human body as per the parameters entered by the users 105;
the processing unit 220 includes a neura tech module 244 that is configured to provide the second dataset after processing the first digital object and the second digital object as input; a secondary digital object on the size and shape of the body defined by body parameter in a pose defined by pose parameter; the neura tech module 244 communicates the second dataset to a post-processing module 256;
the post-processing module 256 is configured to correct the position of apparel draped vertices i.e., the second dataset; the processing unit 220 includes a lookmap module 248 that is configured to map colour and textures of the apparels obtained from the post-processing module 256; the processing unit 220 includes a fitmap module 250; the fitmap module 250 is configured to process the second dataset modified by the post processing module 256 to visualise the fit of the apparel on the body as simulated by the lookmap module 248; and
the visualization module 246 is configured for rendering the first and the second dataset in a three-dimensional representation.

2. The system for simulating three dimensional apparels on three dimensional human body 100 as claimed in claim 1 wherein, the user interface unit 210 includes a data input module 236 for receiving body measurement parameters, cloth parameters and frame number.

3. The system for simulating three dimensional apparels on three dimensional human body 100 as claimed in claim 1 wherein, the dataset collection module 242 collects plurality of apparels draped on plurality of human bodies in a given pose with their body, pose and apparel parameters attached to them.

4. The system for simulating three dimensional apparels on three dimensional human body 100 as claimed in claim 1 wherein, the lookmap module 248 is configured to provide a 3D digital mesh texture or colour to the apparel data received from the post processing module 256.

5. The system for simulating three dimensional apparels on three dimensional human body 100 as claimed in claim 1 wherein, the fitmap module 250 predicts the fit or loose portion of the apparel.

6. The system for simulating three dimensional apparels on three dimensional human body 100 as claimed in claim 1 wherein, the post-processing module 256 includes a clipping correction module 258 that is configured to find and fix the body point to identify the position of the apparel inside or outside the rendered body.

7. The system for simulating three dimensional apparels on three dimensional human body 100 as claimed in claim 1 wherein, the neura tech module 244 is configured to drape the apparel on the user defined body parameters through a NN trainer module 254.

8. A method for simulating three-dimensional apparel on three dimensional human body comprising steps of:
a. receiving first and second digital objects;
b. creating a second dataset through neura tech module 244;
c. removing artifacts with the help of post processing module 256;
d. mapping texture details on an apparel through lookmap module 250;
e. finding areas of the apparel fitting tightly or loosely through the fitmap module 250; and
f. rendering the modified second dataset on user's digital 3D body through visualization module 246.

9. A method of training the neura tech module 244 as claimed in claim 8 comprising steps of:
a. Creating training dataset;
b. Configuring body, pose, apparel parameters as inputs to NN trainer module 254;
c. Initializing neural network model;
d. Providing all inputs from the training dataset to neural network model to generate predicted output;
e. Comparing predicted output with training dataset to calculate loss; and
f. Adjusting weights of each layer to minimize the loss till we reach acceptable loss.

10. A method for creating a training data set as claimed in claim 9 comprising steps of:
a. creating ‘l’ number of bodies with ‘x’ number of body parameters;
b. creating ‘m’ number of apparels with ‘y’ number of apparel parameters;
c. creating ‘n’ number of poses with ‘z’ number of pose parameters;
d. simulating all apparels on all bodies in all poses; and
e. storing all of l*m*n variations as ideal drape data.
